(19) United States
(12) Patent Application Publication
(10) Pub. No.: US 2009/0219403 A1
(43) Pub. Date: Sep. 3, 2009

(54) COMPACT PASSIVE LOW-LIGHT IMAGING APPARATUS

(75) Inventors: Nathaniel J. McCaffrey, Hampton Falls, NH (US); Stephen Saylor, South Hamilton, MA (US)

Correspondence Address: PEPPER HAMILTON LLP, ONE MELLON CENTER, 50TH FLOOR, 500 GRANT STREET, PITTSBURGH, PA, 15219, US

(73) Assignee: SIONYX, INC., Beverly, MA (US)

(21) Appl. No.: 12/333,038

(22) Filed: Dec. 11, 2008

Related U.S. Application Data
(60) Provisional application No. 61/032,533, filed on Feb. 29, 2008.

(51) Int. Cl. H04N 5/225

(52) U.S. Cl. 348/216.1; 348/E05.024

(57) ABSTRACT

A passive portable imaging system for generating a viewable image of a darkened or low-light environment including a sensor made of laser-treated semiconductor material that is sensitive to low-light radiation, in some cases radiation at wavelengths longer than those of traditional visible light imager ranges. The imaging system can be incorporated into a personal electronic product such as a cellular phone or similar compact apparatus, and can provide security to a user who moves in or wishes to view a dark area and doesn't have a light source to illuminate the dark area.

### I. RELATED APPLICATIONS

The present application claims the benefit and priority under 35 U.S.C. §119 of U.S. Provisional Patent Application Ser. No. 61/032,533, entitled “Personal Electronic Device Including Night Imaging System,” to the present inventors and assignee, filed on Feb. 29, 2008. This application is also related to U.S. patent application Ser. No. 12/235,050, entitled “Response-Enhanced Monolithic-Hybrid Pixel,” filed on Sep. 22, 2008, and assigned to the present assignee, the contents of which are hereby incorporated by reference.

### II. TECHNICAL FIELD

The present disclosure generally relates to devices for imaging electromagnetic radiation such as light radiation. The present disclosure more specifically relates to passive imaging using a compact portable device, such as a mobile phone or similar electronic apparatus, that can provide an image in low-light environments.

### III. BACKGROUND

People sometimes move through or need to undertake an activity in darkened areas. These areas can contain obstacles or hazards which are difficult to see with the naked eye or traditional light-imaging devices. In the absence of natural or sufficient lighting, the risk of injury or loss due to such hazards can be reduced by providing active illumination from an artificial source, such as by using a flashlight. Of course, people do not always carry a flashlight because it is burdensome. Moreover, a flashlight requires significant electrical battery power to provide sufficient illumination for adequate inspection and security. In addition, it is not always desired to illuminate a darkened environment so as not to alert or disturb others in the area. In addition, active artificial illumination of a scene has limited range and angular zone of effectiveness, and still usually results in less than optimal viewing or recording of an image.

Traditional imaging and lighting systems are not adapted for visualizing objects or scenes outside the visible range of light wavelengths, and therefore cannot capture an adequate image of an object or a scene in low-light conditions. While some security or military or automotive applications have employed active infrared (non-visible) wavelength illumination for active imaging of targets after dark, the resulting images lack sharpness, color definition, and other useful detail. These systems are expensive and consume too much power to be truly mobile and useful by ordinary persons in daily use.

Imaging systems, e.g. digital cameras, have been adapted to personal electronic devices such as mobile phones equipped with a lens, a memory and a display. Cameras in mobile phones are prevalent, but are commonly limited to imaging in daylight or in ample artificial visible light and are of no help to those wishing to see or capture an image in a low-light environment. Some cameras contain a flash or strobe active illumination source, but this is energy-consuming, costly, and has some of the same drawbacks mentioned above.

A night vision device (NVD) or night vision camera is an optical instrument that allows images to be produced in levels of light approaching total darkness. An NVD typically refers to a device that includes an image intensifier tube. An intensifier tube utilizes a photoelectric effect. As a photon collides with a metal detector plate, the plate ejects several electrons that are amplified into a cascade of electrons, which light up a phosphor screen. The use of image intensifier tubes requires a large form factor that is not feasible to incorporate into a compact personal electronic device, such as a mobile or cellular phone, for the enablement of night vision imaging.

Some of the problems recited here are a result of using traditional imaging technologies and underlying elements in present pixel-based systems, which lack the ability to capture and form useful or adequate images in low-light conditions and are not adaptable to economical, compact, energy-efficient design.

Pixels, or “picture elements,” are the basic light- or color-detection and display elements that form a digital image. Typical digital video and imaging systems use a collection of detector pixels to capture a two-dimensional image field at a capture end (such as a camera) and another corresponding collection of display pixels to display the corresponding two-dimensional image at a display end (such as a monitor). In digital imaging systems, an array of light-sensitive pixels, each including a light sensor or detector, respond to an intensity of incident light at each pixel location, providing an electrical output representative of the incident light. The output of an imager can be referred to as an image. Motion or video cameras repeat the process described above, but permit a time-sequence to be captured, for example at regular intervals, so that the captured images can be replayed to recreate a dynamic scene or sequence.

Most film and digital pixel imagers include wavelength-specific sensors or detectors. The chemical composition of the film or the design of the digital pixels and associated filters determines the range of wavelengths of light to which the film or pixels respond. Practically, a detector or imager has a frequency response that is optimized to provide images of light in the range of wavelengths the imager is designed for. The most common examples are sensitive to visible light (e.g., red, green, blue, and combinations thereof. Visible light corresponds to the range of wavelengths of electromagnetic radiation to which our eyes are sensitive, and is generally in the range of 400 to 750 nanometers (nm).

Special film and digital pixel imagers are designed for low-Light operation to provide night vision capability for military, security, or other special applications in which an illumination source is not available to cause a visible light image. Low-light or night vision imagers rely on detecting and imaging frequencies below (wavelengths longer than) the visible (red) wavelengths, and are sometimes called infra-red (IR) detectors. IR detection is more suited for picking up heat emissions from objects such as a person's body or a vehicle. IR radiation itself can be roughly divided into sub-spectra including the near-infra-red (NIR) having wavelengths between about 750 to 1100 nm, short-wave-infra-red (SWIR) having wavelengths between about 1100 and 2500 nm, medium-wave-infra-red (MWIR) having wavelengths between about 2500 and 8000 nm, and long-wave-infra-red (LWIR) having wavelengths between about 8000 and 12000 nm. These ranges are defined somewhat arbitrarily, and are given merely for simplifying the following discussion, and those skilled in the art will appreciate the generality of the discussion as it relates to the hands of wavelengths of the electromagnetic spectrum.

Present visible light imaging cameras have used silicon devices made with CID, CCD, or CMOS APS architectures. The low cost and efficient collection of photons from 400-750 nm wavelengths has enabled silicon devices. Extending the use of silicon imagers into the near infrared (NIR) band requires a greater volume of material to detect these wavelengths because of silicon's relatively low absorption coefficient in this wavelength range. This increases the size of the detectors and causes increased leakage current and requires expensive manufacturing processes or higher voltages to operate. The use of thick silicon substrates also limits the ability to integrate other devices in the design of the imaging system.

FIG. 1 illustrates an exemplary simplified imaging scenario in bright daylight according to the prior art. An imaging system 10 is used to generate an image of an object or scene 120 illuminated by daylight 110. Visible light rays 115 illuminate the scene, and incident light 130 shines upon object or scene 120. Reflected light 140 results from illumination of scene or object 120. Some or all of reflected light 140 is captured by a lens 150. Rays 160 within imaging system 10 are collected, and collected rays 160 form image 180 on image surface 170. Focusing and other aperture control and ancillary components of imaging system 10 are not shown for the sake of clarity and generality. Those skilled in the art will appreciate how the above applies to still image photography (digital or analog film varieties) or to motion picture photography and the like.

Note that sufficient lighting is required in typical imaging systems to enable a good signal to be available to imaging system 10 to generate a sharp and clear picture or image 180 of object or scene 120. Insufficient light 115 and 130 or ineffective capture of light 140 and 160 or inadequate sensitivity of image surface 170 (film or digital pixels) will result in an unacceptable image 180, or none at all. Also, there is a limited range of wavelengths of light that are suitable for capture in imaging system 10, beyond which the sensitivity of the system is reduced or non-existent and does not provide adequate images.

One solution for taking images when there is insufficient ambient light is to provide artificial lighting. FIG. 2 illustrates a simplified scenario for imaging using artificial illumination. A source of artificial active illumination 210 comprises a power source 214 that powers a light source 212 emitting electromagnetic rays 216 within an illumination zone 218. The rays 216 and artificial illumination source 210 can be designed to emit visible (e.g., white or colored) light such as from a flashlight, floodlight, or strobe light, or they can be designed to flood the illumination zone 218 with non-visible radiation (e.g., infrared).

Scene or object 220 is illuminated as discussed above by incident rays 230, and scatters or reflects reflected rays 240 which can be detected by an imager 20. As discussed above, imager 20 includes a collector or lens 250 that directs collected rays 260 to a suitable imaging surface 270 to yield image 280. Therefore, a visible light image as well as an artificially-illuminated image from a non-visible active illumination source 210 are possible. However, these actively illuminated imaging scenarios require a relatively large power source to flood the area being imaged with light. This also causes these systems to be large and expensive as they require powerful sources of visible or infra-red light and larger batteries for the same if they are to be portable. Security, automotive and military applications of this technology are in existence.

FIG. 3 illustrates yet another imaging scenario according to the prior art. Here an object or scene 320 is to be imaged passively in a low-light (e.g., night-time) environment and without artificial active illumination. This avoids the need for the large and expensive power hungry illumination source shown in the earlier figures. In this situation imaging system 30 must be constructed to collect using lens 350 enough collected radiation 360 to create a useful image 380 on imaging surface 370. These systems generally yield poor images 380, without sufficient color resolution, and are often grainy and unclear. These systems are also usually expensive and fragile and do not lend themselves to being mobile or portable in a useful way to individuals. High internal amplification of the collected light signals, and costly processing and filtering circuits are required to yield image 380. The signal-to-noise ratio of such systems is usually relatively poor compared to images that can be generated using bright (daylight) lighting and the like.

Other draw-backs to present low-light imaging systems are that they require expensive, unreliable, and awkward and bulky apparatus for mechanical movement of infrared blockers or filters. For example, because infrared signals can degrade the color content of traditional images, traditional imagers insert a filter to remove infrared signals or energy content from a collected signal. As a result, the signal lacks any information that is carried in the infrared portion of the spectrum, and needs an electromechanical apparatus to insert and remove the infrared filter block from the path of the collected light. These traditional low-light systems also incorporate very costly exotic materials such as Ge and InGaAs, raising their price to an end user.

There is a need for improved imaging in a variety of lighting situations, especially in low-light environments. Also, there is a need for lower cost, energy-efficient, and more reliable and compact systems that can perform adequate imaging in a variety of lighting situations such as low-light or night-time environments without needing to rely on artificial active illumination of the environment.

### IV. SUMMARY

Embodiments herein include a portable, low cost and low power day and night vision camera included in a personal electronic device. A personal electronic device embodied herein may include, for example, and without limitation, a mobile phone, a personal digital assistant, music player, compact camera product, communicator, and so on.

Some embodiments are specifically directed to a system for imaging in a low-light environment, including a light collector for passively collecting radiation from the low-light environment; a photosensor comprising a laser-processed semiconductor sensitive to at least a range of wavelengths of said collected radiation; a processor for receiving an output from said photosensor and processing said output of said photosensor to generate image data; and a display apparatus for displaying an image corresponding to said generated image data.

These systems can include pixel and imaging components, including laser-processed semiconductor elements treated with pulsed laser light, e.g., short-pulse laser light to create advantageous properties thereof, including properties conducive to detection and response to low lighting and night light and long wavelength light conditions.

Other embodiments and uses for the methods and systems given herein can be developed by those skilled in the art upon comprehending the present disclosure.

### V. BRIEF DESCRIPTION OF THE DRAWINGS

For a fuller understanding of the nature and advantages of the present invention, reference is be made to the following detailed description of preferred embodiments and in connection with the accompanying drawings, in which:

FIG. 1 illustrates a simplified imaging scenario using ambient daylight according to the prior art;

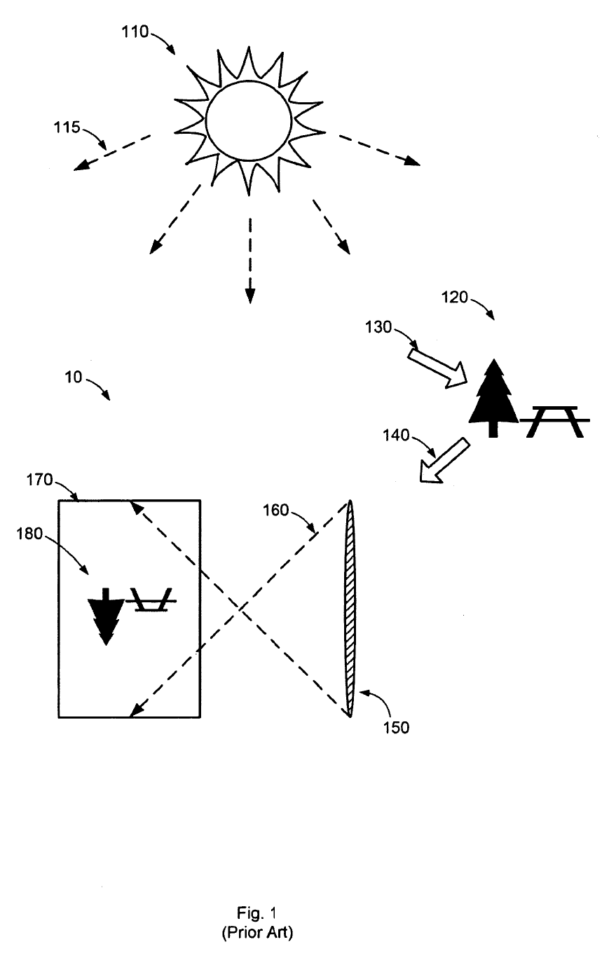

FIG. 2 illustrates a simplified imaging scenario using active illumination according to the prior art;

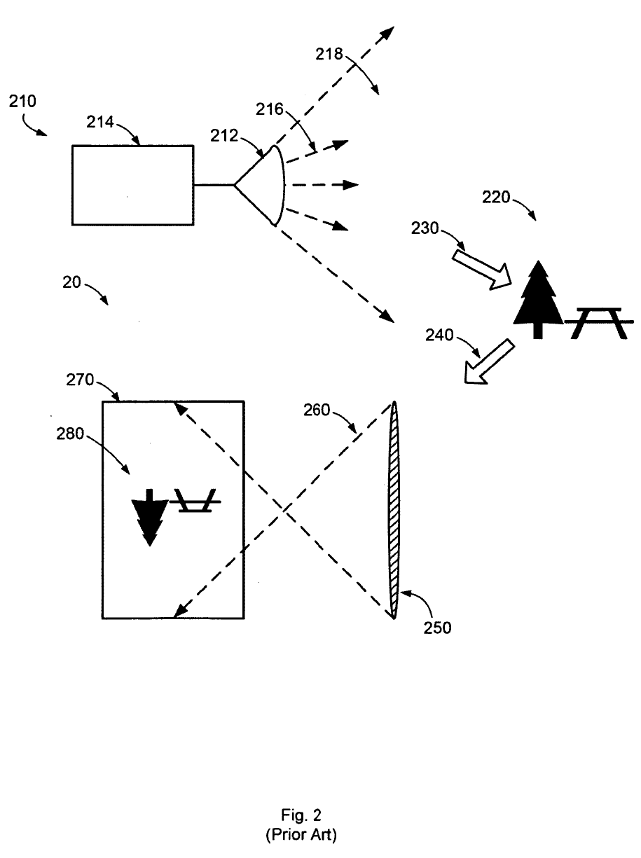

FIG. 3 illustrates a simplified passive imaging scenario in low light;

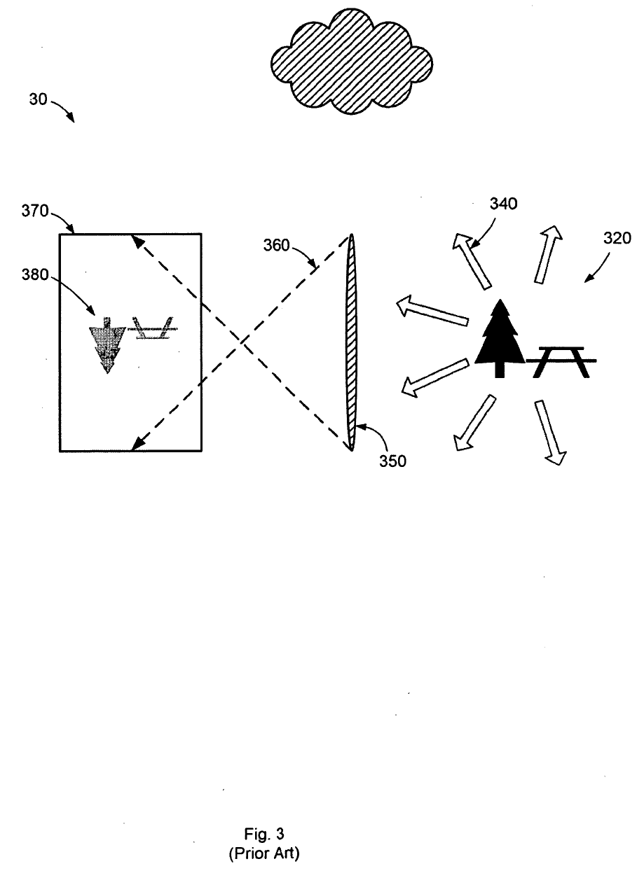

FIG. 4 illustrates a simplified passive imaging scenario in low light with post-processing of the image;

FIG. 5 illustrates a simplified passive imaging scenario in low light with an enhanced collector;

FIG. 6 illustrates a user using a portable hand-held device to passively image a low-light scene;

FIG. 7 illustrates a basic outline of the components of an exemplary personal low-light imaging system; and

FIG. 8 illustrates an exemplary pixel that can be used in a personal low-light imaging system.

### VI. DETAILED DESCRIPTION

Many people carry personal electronic devices on a consistent basis. Incorporation of a true night vision imaging system into, for example, a cell phone provides added security and navigational capabilities to the cell phone user in low ambient light conditions.

In an exemplary embodiment, a day and night vision camera may include a photo sensing layer that is manufactured from a laser-processed semiconductor. Such a photo sensing layer may be formed, for example, with femtosecond laser pulses, as disclosed in U.S. Pat. No. 7,057,256, which is incorporated bat reference herein in its entirety. The semiconductor material may include, without limitation, a doped semiconductor material, such as sulfur-doped silicon.

The photo sensing layer, and hence the camera, may have a broad spectral response. In an embodiment, the camera may exhibit a photoelectric response to electromagnetic radiation in the visible and near infrared ranges. In an embodiment, the camera may have a photoelectric response to wavelengths of light from about 250 nm to about 3500 nm. In an embodiment, the camera may have a photoelectric response to wavelengths of light from about 250 nm to about 1200 nm. In an embodiment, the camera may have a photoelectric response to wavelengths of light from about 400 nm to about 1200 nm. Other wavelength ranges of photoelectric response in the visible and near infrared spectral ranges are encompassed within the scope of this disclosure.

In an exemplary embodiment, the photo sensing layer may exhibit a responsivity of greater than about 1 A/W for incident electromagnetic radiation having a wavelength in a range of about 250 nm to about 1050 nm, and greater than about 0.1 A/W for incident electromagnetic radiation having a wavelength in a range of about 1050 nm to about 3500 nm. In an alternate embodiment, the photo sensing layer may exhibit a responsivity of greater than about 1 A/W for incident electromagnetic radiation having a wavelength in a range of about 400 nm to about 1050 nm, and greater than about 0.1 A/W for incident electromagnetic radiation having a wavelength greater than about 1050 nm.

It is noted that the photo sensing layer and camera described herein do not require a bulky image intensifier tube typically used in conventional night vision devices. Thus, the small form factor of the day and night vision camera disclosed herein enables eight vision imaging in a small and portable personal electronic device, such as a mobile phone, personal digital assistant (PDA), compact camera, portable music player (e.g., MP3 player), etc. The small form factor beneficially enables convenient transport of the device and covertness when the user is confronted by a threatening or emergency situation.

In addition, the day and night, or night vision, cameras embodied herein using the laser-processed semiconductor do not require any artificial illumination for operation in a night vision imaging mode. This form of night vision is commonly referred to as “passive” night vision. Because artificial illumination is not required, significant power may be saved, and covert operation of the device may be enabled. The use of the device may facilitate navigation in complete darkness. The night vision sensitivity may utilize Rayleigh atmospheric scattering of reflections incident on the photo sensing layer in the near infrared region with wavelengths ranging from about 750 nm to about 1200 nm. This night vision technique utilizes long wavelength light inherent in the night sky and does not require illumination from the device, as is typical in an “active” night vision device.

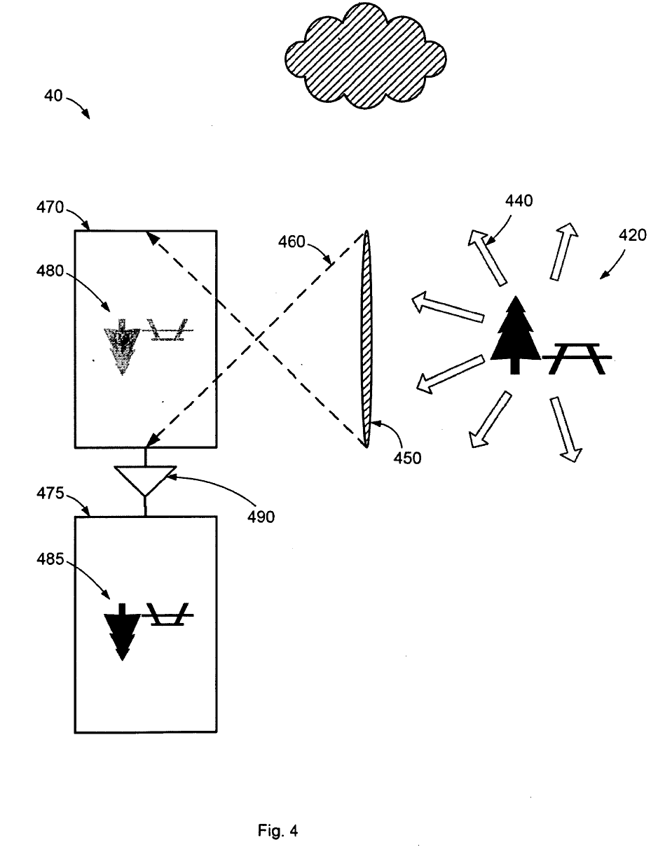

FIG. 4 illustrates a simplified low-light imaging system 40 that can create images (still or moving) of a scene or object 420 in low-light (or night-light) environments. Objects 420 reflect, scatter, and naturally emit electromagnetic radiation 440, including radiation in various infra-red (non-visible) wavelength ranges by virtue of their composition and temperature. In a completely passive environment, radiation 440 can be considered partially or entirely radiated. Radiated energy 440 is collected by imaging system 40 through a lens 450 or other appropriate radiation collector. Collected radiation 460 is directed to an imaging surface 470 which can include a plurality of imaging pixels arranged in an array. Each pixel can generate an output signal indicative of an intensity of incident collected radiation impinging on the location of that pixel. The collection of pixel output signals is coordinated as a two-dimensional image output 480.

As discussed earlier, low-light passive imaging can yield poor or relatively lesser images in some systems. Therefore, an amplification and/or other circuitry 490 can be used to digitally or otherwise filter or enhance image 480 to generate an enhanced image 485 on some display, grid, or other output surface 475. The output surface can include a logical element such as a memory space, data structure, or circuit, and is not limited to physical viewable embodiments in this component.

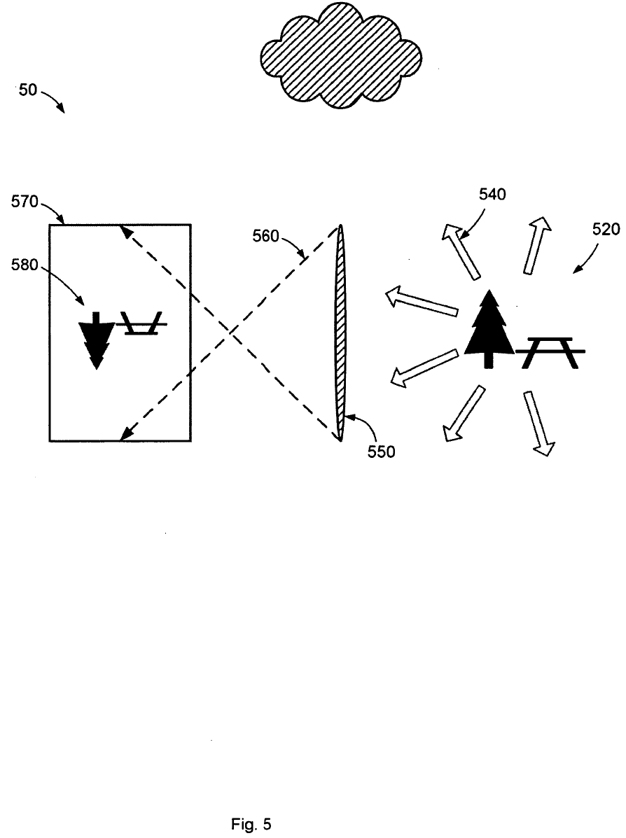

FIG. 5 illustrates an exemplary and simplified arrangement of an imaging system 50 that is adapted for capturing low-light images such as those taken at night time or in unlit indoor spaces or in poorly lit environments. An object or scene 520 reflects, scatters, and radiates radiation 540 from whatever sources or intrinsic causes exist, for example, due to the thermal radiation of object 520. The radiated energy 540 is captured by passive low-light imaging system 50 using a lens 550 or similar collector. Collected radiation 560 is transferred to imaging surface 570, which is specially constructed and arranged as will be described below, to create an acceptable image 580 without the need for special power-consuming active illumination of object or scene 520.

In some embodiments, the imaging system 50 and/or imaging surface 570 include special pixels for detection of low levels of radiation in a range of wavelengths, including non-visible (e.g., infrared) wavelengths. Therefore, with special passive low-light imager 50 a user could “see” objects that are otherwise too dark to discern using conventional imagers or the naked eye. Furthermore, in some embodiments, the present system 50 can be made to be portable, hand carried, and even integrated with a personal electronic apparatus such as a cellular phone, PDA, pocket digital camera, music player, or other personal electronic devices as given elsewhere herein or would be appreciated by those skilled in the art. This kind of personal low-light imaging system can provide safety while moving about at night, such as if the user is walking in a poorly-lit building, parking lot, or any indoor or outdoor space lacking sufficient fighting or security to allow safe movement in low-light conditions. The device will also allow a person to investigate the nature of a dark area such as a room or office space or utility space prior to entering the space to avoid unseen hazards. In addition, the user of such a device can be assisted in locating or finding misplaced or lost articles in the dark when it is not possible or convenient or desirable to turn on a light to illuminate the area.

Reference is made to pending U.S. patent application Ser. No. 12/235,050, entitled “Response-Enhanced Monolithic-Hybrid Pixel,” filed on Sep. 22, 2008, and assigned to the present assignee, the contents of which are hereby incorporated by reference. This and other publications by the present inventors and assignee provide suitable low-light detectors capable of detection of electromagnetic radiation in the short infrared SWIR ranges and other wavelengths enabling night vision passive detection. These pixels are especially sensitive and adapted to absorption of long wavelength radiation to form adequate images enhanced by said long wavelength energy content. The present systems can be constructed using the afore-mentioned laser-doped silicon pixel elements, inserted into the form factor of the portable personal electronic device of choice, e.g., a cellular phone or similar apparatus.

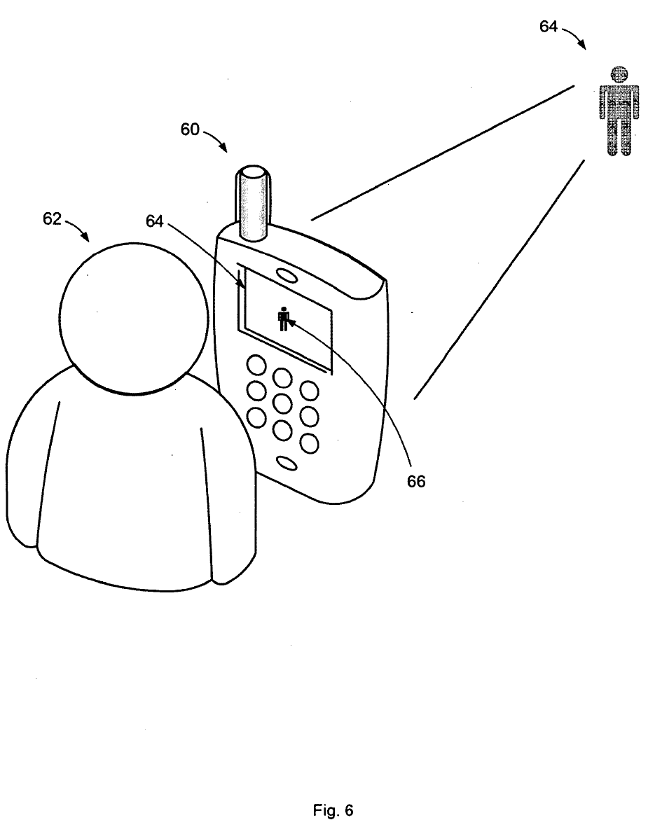

FIG. 6 illustrates an exemplary portable personal electronic device 60 for low-light imaging without the need for active illumination. In some embodiments, device 60 is battery powered. The device is intended to be readily portable and hand-held by a user 62, who can charge the device 60's battery (not shown) and transport the device for use as a cellular phone, camera, and night-vision aid. As intended by the illustration, this device can be combined into the form factor and packaging of a cellular telephone that a user can carry about conveniently, and has a user interface and input/output apparatus such as a keypad, control buttons, a microphone, speaker, and a display screen 64 capable of displaying an image 66 of object 64 that is otherwise not visible to user 62. For example, if object 64 is an intruder or unwanted person or animal, its thermal signature or other radiated SWIR emissions can be captured by device 60 and displayed to the user 62. While a flash or other active illumination element could be incorporated into device 60, the system is intended to be capable of passively imaging objects and scenes using non-visible captured light, or a combination of visible and non-visible light. A permanent record or snapshot of the contents of display screen 64 may be captured to a memory device such as a flash memory card or internal RAM of the device 60. Also, wireless connectivity can enable device 60 to transmit such captured images to another location over a network.

The present systems Are designed using the laser-treated semiconducting detectors discussed above, and can utilize custom circuitry for operating such detectors. In addition, circuitry for processing pixel outputs and images that are similar to those in present use can be used to enhance, improve, amplify, filter, resolve, sharpen, compress, encode, or otherwise treat the captured low-light images of the present imaging system.

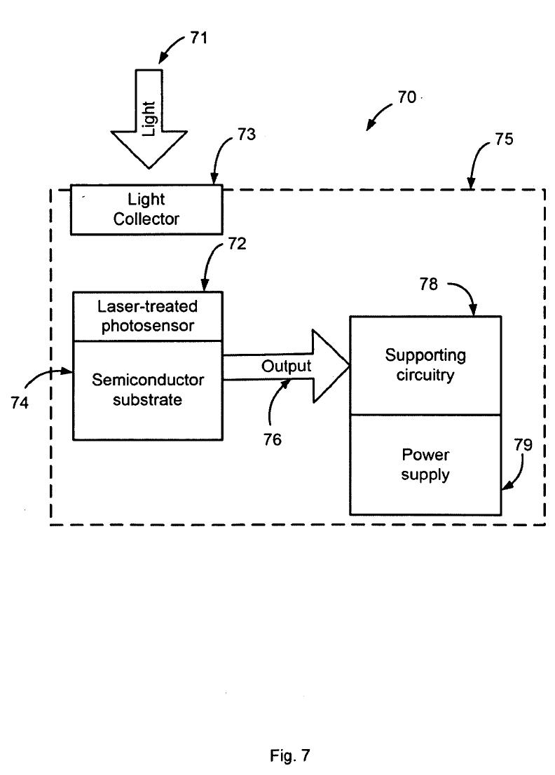

FIG. 7 illustrates an exemplary overview of the main components of an exemplary personal low-light imaging system 70. The system is sensitive to one or more frequencies of incident detected light 71 which arrives at a laser-treated photosensor 71. The light 71 may of course first pass through lenses or optical elements 73, to capture said light. The laser-treated photosensor 72 may be disposed on a semiconductor substrate 74, and provides an output 76 such as an output electrical signal or data to supporting circuitry 78. Supporting circuitry 78 can include any of the apparatus, hardware and software described herein or apparent to those skilled in the art upon review of die present discussion. Image processing hardware and software, amplifiers, signal processors, encoders, filters, and other input/output (I/O) apparatus and components are among those things which can be included in the supporting circuitry 78. The circuitry 78 and other components of system 70 can be powered by a portable and compact power source, e.g., a DC battery. A memory apparatus, e.g., flash, NAND, microcard, SRAM, or others can be connected to the circuitry 78 for storage of captured still or video images from low-light imaging system 70. Also, the entire system can be contained within a housing 79 to protect the components of the system and provide a convenient way for handling, holding, and storing the system. The system can be compact, like a personal electronic product such as a cellular phone or camera, and can be relatively easily, kept on a user's person, e.g., in the user's hand or pocket without undue inconvenience.

In some embodiments, the present system can obviate the need in prior low-light imagers for using an infra-red filter and moving the filter in and out of the light path. The present system can use one or more sensors, some of which are sensitive to infra-red radiation, to collect images in a variety of light conditions without illumination by the system or its user. That is, the present system can be made to passively collect and create still or video images of a low-light environment by activating or deactivating sets of corresponding photosensors in the system such as those described herein.

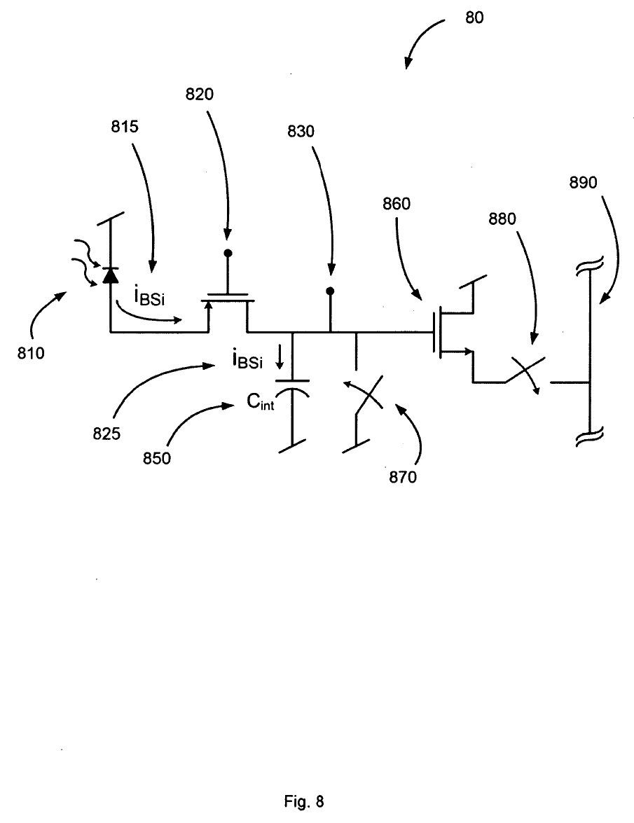

FIG. 8 illustrates an exemplary pixel 80 comprising a photonic detector 810 of the laser-treated type (sometimes referred to as “black silicon” photodetector) which can be integrated into a same substrate as the readout circuitry for the pixel. Radiation in certain wavelength ranges incident on pixel 80 is detected by detector 810 and creates a corresponding current i_{BSi} 815, which represents an electrical output, to flow from the detector. A direct injection detector bias 820 is applied to hold a relatively constant voltage across the detector 810.

Integration capacitance Cᵢₙₜ, 850 which may be physical or parasitic and represents a collection point, integrates the charge collected by flow of current i_{BSi} 825 through the capacitor 850 over some time. Note that in this embodiment, currents 825 and 815 are equivalent and integrate on Cᵢₙₜ, 850. A resultant output voltage is provided at the input of signal buffer 860, which represents an output point. Contact post 830 in this exemplary embodiment is not used but may be exposed at the surface of pixel 80, and can be used as will be described below to couple to a hybridized detector element to enhance the response of a pixel. Signal buffer 860 is addressed by column 890 and row enable switch 880 for non-destructive reading of pixel 80. It should be appreciated that a source follower buffer, row switch, and column line are merely examples of a generally-realizable output port, which here includes circuit elements 860, 890, and 880 only by way of example. A reset switch 870 shorts out capacitor 850 thus resetting the collection process. During normal operation detector 810 is reverse biased by the bias voltage applied to terminal 820 as mentioned above.

In some applications, the pixel 80 and its laser-treated detector 810 allow for detection and sensitivity to long wavelength radiation including in ranges beyond the visible range of the electromagnetic spectrum, such as the near infra-red or the infra-red ranges.

It will be appreciated that once the present passive low-light imaging system is used, it can be coupled to a data storage or output apparatus, such as flash memory or other suitable means, to enable permanent recording or storage of the captured images. For example, still digital photographs can be generated by storing the captured images to a storage medium such as those used in digital cameras. And moving pictures or animated scenes can also be captured onto a data storage medium for collecting periodic frames of images to generate a dynamic sequence thereof. In addition, sound may be captured to create an audio-visual record of the scene.

The present invention should not be considered limited to the particular embodiments described above, but rather should be understood to cover all aspects of the invention as fairly set out in the attached claims. Various modifications, equivalent processes, as well as numerous structures to which the present invention may be applicable, will be readily apparent to those skilled in the art to which the present invention is directed upon review of the present disclosure. The claims are intended to cover such modifications.

We claim:

1. A system for imaging in a low-light environment comprising:
a light collector for passively collecting radiation from the low-light environment;
a photosensor comprising a laser-processed semiconductor sensitive to at least a range of wavelengths of said collected radiation;
a processor for receiving an output from said photosensor and processing said output of said photosensor to generate image data; and
a display apparatus for displaying an image corresponding to said generated image data.

2. The system of claim 1, said light collector comprising an optical lens.

3. The system of claim 1, said laser-processed semiconductor comprising at least a layer formed by exposure to repeated pulses of laser radiation during a manufacturing process thereof.

4. The system of claim 3, said semiconductor comprising a silicon semiconductor.

5. The system of claim 1, said further comprising a plurality of similarly constructed photosensors arranged in an arrangement to each provide an output thereof to collectively generate image data.

6. The system of claim 1, further comprising a power supply.

7. The system of claim 1, further comprising a housing that houses the elements of said system in a format that is portable for at user to carry about.

8. The system of claim 1, further comprising a memory apparatus for storing said image data.

9. The system of claim 1, said image data comprising a still image data.

10. The system of claim 1, said image data comprising a video sequence of image data.
